(19) United States
(12) Patent Application Publication
(10) Pub. No.: US 2012/0199903 A1
(43) Pub. Date: Aug. 9, 2012

(54) SEMICONDUCTOR DEVICE HAVING A SUPER JUNCTION

(75) Inventors: Yung-Fa LIN, Hsinchu (TW); Shou-Yi HSU, Hsinchu (TW); Meng-Wei WU, Hsinchu (TW); Main-Gwo CHEN, Hsinchu (TW); Yi-Chun SHIH, Hsinchu (TW)

(73) Assignee: ANPEC ELECTRONICS CORPORATION, Hsinchu (TW)

(21) Appl. No.: 13/349,006

(22) Filed: Jan. 12, 2012

(30) Foreign Application Priority Data
Feb. 5, 2011 (TW) 100115347

(51) Int. Cl. H01L 29/78

(52) U.S. Cl. 257/335; 257/E29.256

(57) ABSTRACT

A semiconductor device having a super junction includes: a substrate having a first electrical type; a main body including a base part that has the first electrical type, and a modified part that has a second electrical type opposite to the first electrical type; a source zone contacting the modified part oppositely of the substrate, and having the first electrical type; and a gate structure having a dielectric layer that contacts the source zone, and a conductive layer formed on the dielectric layer oppositely of the main body.

### CROSS-REFERENCE TO RELATED APPLICATION

This application claims priority of Taiwanese application no. 100115347, filed on May 2, 2011.

### BACKGROUND OF THE INVENTION

1. Field of the Invention

This invention relates to a semiconductor device having a super junction, and more particularly to a power transistor having a super junction.

2. Description of the Related Art

Referring to FIG. 1, a conventional semiconductor device has a plurality of power transistors, each of which has a super junction, and each of which includes a substrate 11, a main body 12, a source zone 13, a gate structure 14, and a contact 15.

The substrate 11 is made of a semiconductor material having a first electrical type.

The main body 12 includes a base part 121 and a filling part 122. The base part 121 has the first electrical type and has a majority carrier concentration lower than that of the substrate 11. The filling part 122 has a second electrical type opposite to the first electrical type, and is connected to the base part 121. An interface between the base part 121 and the filling part 122 defines the super junction. The filling part 122 has an epitaxial region 123 and a well region 124 formed on the epitaxial region 123.

The source zone 13 is formed in the well region 124 of the filling part 122, and has the first electrical type. The source zone 13 has a major carrier concentration larger than that of the base part 121 of the main body 12.

The contact 15 is mainly made of metal material, and partially contacts the source zone 13 and the well region 124. Preferably, the contact 15 is mainly made of aluminum, copper, etc.

The gate structure 14 includes a dielectric layer 141 and a conductive layer 142. The dielectric layer 141 is formed on the base part 121 to contact the well region 124. The conductive layer 142 is formed on the dielectric layer 141, and is spaced apart from the base part 121 by the dielectric layer 141. The dielectric layer 141 is made of an insulative material, such as silicon dioxide, silicon nitride, or a combination thereof. The conductive layer 142 is made of a conductive material, such as metal, polycrystalline silicon, etc.

The substrate 11 serves as a drain, the well region 124 serves as a well, the source zone 13 serves as a source, and the gate structure 14 serves as a gate. When the first electrical type is n-type, the second electrical type is p-type. On the contrary, when the first electrical type is p-type, the second electrical type is n-type.

When a predetermined voltage is applied between the substrate 11 and the conductive layer 142 of the gate structure 14 that correspond to the source zone 13, the voltage on the gate structure 14 makes the well region 124 to form a channel so that a current from the substrate 11 passes through the channel to the source zone 13, thereby actuating the power transistor.

The conventional power transistor is formed by the following steps. First, an epitaxial layer, which has the first electrical type, is grown on the substrate 11, and is subjected to lithography and etching processes to form the base part 121 and a trench. The trench is indented from a top face of the base part 121 toward the substrate 11. Then, the filling part 122 is formed by filling the trench with a filling material having the second electrical type using an epitaxial process. The base part 121 and the filling part 121 form the main body 12.

Thereafter, the dielectric layer 141 and the conductive layer 142 are sequentially deposited on the main body 12 to form the gate structure 14.

Next, second electrical type carriers are implanted into the filling part 122 so as to form a well-forming region that is implanted with the second electrical type carriers, and the epitaxial region 123 that is not implanted with the second electrical type carriers. Then, first electrical type carriers are implanted in the well-forming region so as to form the source zone 13 that has the first electrical type. Finally, the contact 15 is formed to contact the source zone 13 and the well region 124 so as to obtain the power transistor.

However, since, in the conventional power transistor, the filling part 122 is epitaxially formed in the trench that has a damaged crystal lattice due to the etching process, the super junction between the base part 121 and the filling part 122 is likely to have defects, e.g., voids, dislocations, etc., and thus is not a crystal lattice continuous interface. This may affect the transmission of the electrical charges when the power transistor is operated. Besides, because the super junction between the base part 121 and the filling part 122 is a heterogeneous interface, the electrical charges may be trapped and accumulated in the super junction, thereby resulting in leakage current, poor current stability, and inferior reliability.

### SUMMARY OF THE INVENTION

Therefore, an object of the present invention is to provide a semiconductor device having a super junction that can overcome the aforesaid drawbacks associated with the prior art.

According to this invention, a semiconductor device having a super junction comprises:

a substrate made of a semiconductor material;

a main body that is disposed on the substrate and that includes a base part and a modified part that contacts the base part and that has an electrical type opposite to that of the base part, the modified part including a central region, and a diffusion region that surrounds the central region to separate the central region from the base part, and that is crystal lattice continuous to the base part;

a gate structure having a dielectric layer formed on the main body oppositely of the substrate and a conductive layer formed on the dielectric layer oppositely of the main body; and

a source zone that is formed in the main body and that contacts the dielectric layer of the gate structure.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a fragmentary schematic diagram of a conventional semiconductor device;

FIG. 2 is fragmentary schematic diagram of the first preferred embodiment of a semiconductor device according to this invention;

FIG. 3 is a modification of the first preferred embodiment showing that a modified part of the semiconductor device has a height less than a sum of a height of a base part and a height of a substrate, and that a bottom end of the modified part extends into the substrate;

FIGS. 4 to 6 are fragmentary schematic diagrams illustrating consecutive steps of a method for fabricating the semiconductor device of FIG. 2;

FIG. 7 is a fragmentary schematic diagram of the second preferred embodiment of a semiconductor device according to this invention;

FIG. 8 is a modification of the second preferred embodiment showing that a modified part of the semiconductor device has a height less than a sum of a height of a base part and a height of a substrate, and that a bottom end of the modified part extends into the substrate; and

FIGS. 9 to 11 are fragmentary schematic diagrams illustrating consecutive steps of a method for fabricating the semiconductor device of FIG. 7.

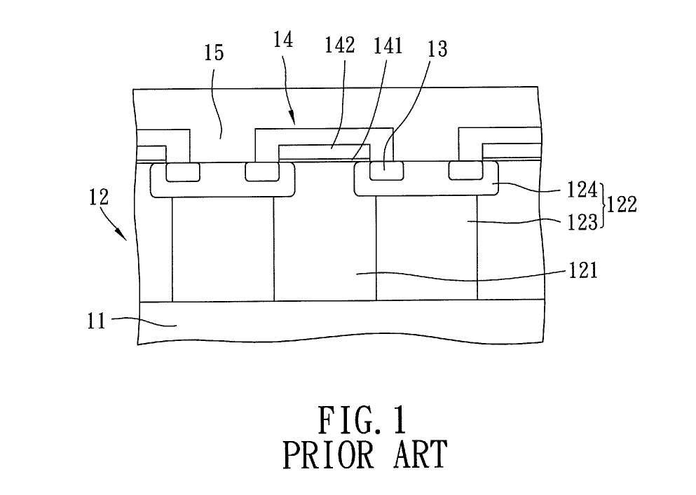

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

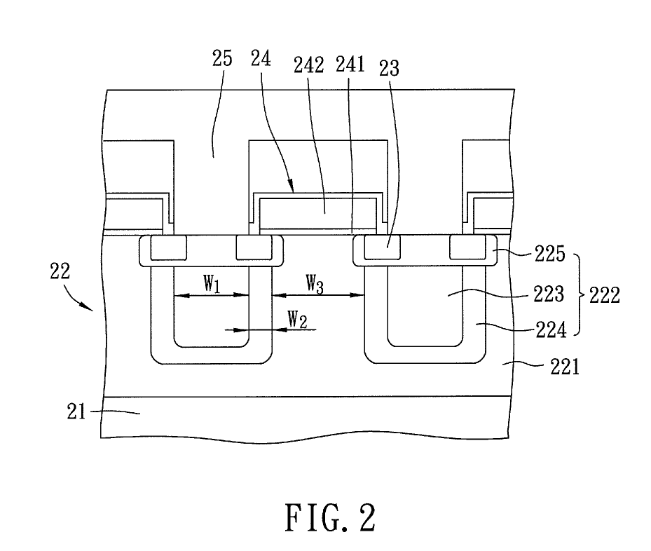

Referring to FIG. 2, the first preferred embodiment of a semiconductor device according to this invention includes a plurality of power transistors, each of which has a super junction, and each of which includes a substrate 21, a main body 22, a source zone 23, and a gate structure 24.

The substrate 21 is made of a semiconductor material having a first electrical type and is epitaxially formed to have a predetermined majority carrier concentration.

The main body 22 includes a base part 221 and a modified part 222. The base part 221 is disposed on an upper surface of the substrate 21, has the first electrical type, and has a majority carrier concentration lower than that of the substrate 21. The modified part 222 contacts the base part 221, and has a second electrical type opposite to the first electrical type. In this preferred embodiment, the first electrical type is n-type, and the second electrical type is p-type. The n-type and p-type are simply used to distinguish the electrical properties of semiconductors, and thus, when the first electrical type is p-type, the second electrical type is n-type.

The modified part 222 includes a central region 223, a diffusion region 224, and a well region 225. The diffusion region 224 surrounds the central region 223 to separate the central region 223 from the base part 221, and has a majority carrier concentration gradually reduced from an outer surface of the central region 223 to the base part 221. The well region 225 has the p-type, is disposed on the central region 223 and the diffusion region 224, and surrounds and contacts the source zone 23. An interface between the diffusion region 224 and the base part 221 is crystal lattice continuous, and defines the super junction.

The source zone 23 contacts the well region 225 of the modified part 222 oppositely of the substrate 21, and has the n-type. The source zone 23 has a majority carrier concentration not lower than that of the base part 221.

The gate structure 24 is formed on a top face of the main body 22 oppositely of the substrate 21, and includes a dielectric layer 241 that contacts the source zone 23, and a conductive layer 242 that is formed on the dielectric layer 241 and is spaced apart from the main body 22 by the dielectric layer 241. The dielectric layer 241 is made of an insulative material, such as silicon dioxide, silicon nitride, etc. The conductive layer 242 is made of a conductive material, such as polycrystalline silicon.

In the first preferred embodiment, the power transistor further comprises a contact 25. The contact 25 is connected to the source zone 23 and the well region 225, and is mainly made of metal. Preferably, the contact 25 is made of a material selected from copper, aluminum, etc.

In this embodiment, the substrate 21 serves as a drain, the well region 225 serves as a well, the source zone 23 serves as a source, and the gate structure 24 serves as a gate. As shown in FIG. 2, in this embodiment, the power transistors of the semiconductor device are arranged side by side, and the substrate 21, the base part 221, and the contact 25 are common for all of the power transistors. In such case, the power transistors are connected in a parallel connection. Of course, the semiconductor device can include a single power transistor in other embodiments.

When a predetermined voltage is applied between the substrate 21 and the conductive layer 242 of the gate structure 24 that correspond to the source zone 23, the voltage on the gate structure 24 makes the well region 225 to form a channel for passage of electrical charges so that a current from the substrate 21 passes through the channel to the source zone 23, thereby actuating the power transistor.

In the preferred embodiment of this invention, because the super junction is unlikely to have voids and dislocations attributed to the crystal lattice discontinuity at the super junction, the electrical charges can move smoothly to have a stable current value and is unlikely to be trapped and accumulated in the super junction so that the aforesaid drawback associated with the prior art can be eliminated, and so that the semiconductor device of this invention has good reliability.

The central region 223 in each of the power transistors has a width (W1) not greater than a distance (W3) between two adjacent modified parts 222 (see FIG. 2). The central region 223 is symmetrically disposed in the modified part 222. That is to say, the widths (W2) of the diffusion region 224 at two opposite sides of the central region 223 are the same. Besides, the width of the modified parts 222 (i.e., W1+2×W2) is equal to the distance (W3) between two adjacent modified parts 222.

Preferably, the width (W1) of the central region 223 of each of the modified parts 222 is not greater than five-seventh of the distance (W3) between the two adjacent modified parts 222, and the diffusion region 224 of each of the modified parts 222 has a shortest width (W2) not less than one-fifth of the width (W1) of the central region 223 of each of the modified parts 222. Accordingly, when the semiconductor device is switched on, occurrence of a leakage current may be avoided, and the current in the power transistor is more stable and accurate.

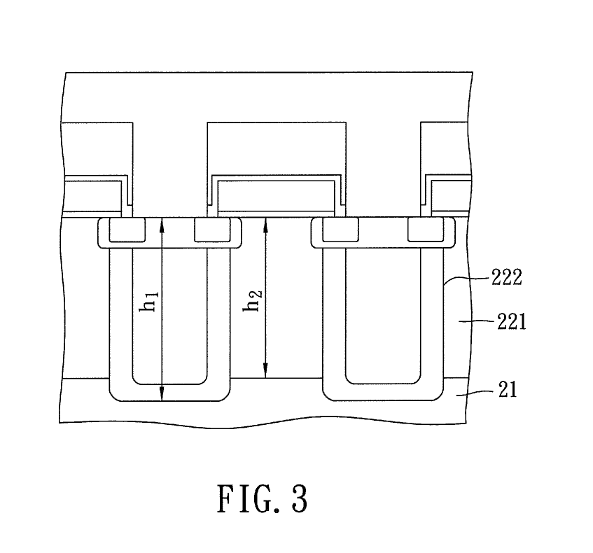

In this embodiment, the modified part 222 has a height (h1) less than a sum of a height (h2) of the base part 221 and a height of the substrate 21. In FIG. 2, a bottom end of the modified part 222 is formed in the base part 221. Alternatively, as shown in FIG. 3 which shows a modification of the first preferred embodiment, the bottom end of the modified part 222 can extend into the substrate 21, but does not penetrate through the substrate 21, i.e., the substrate 21 should be continuous, such that the power transistors can be parallelly connected.

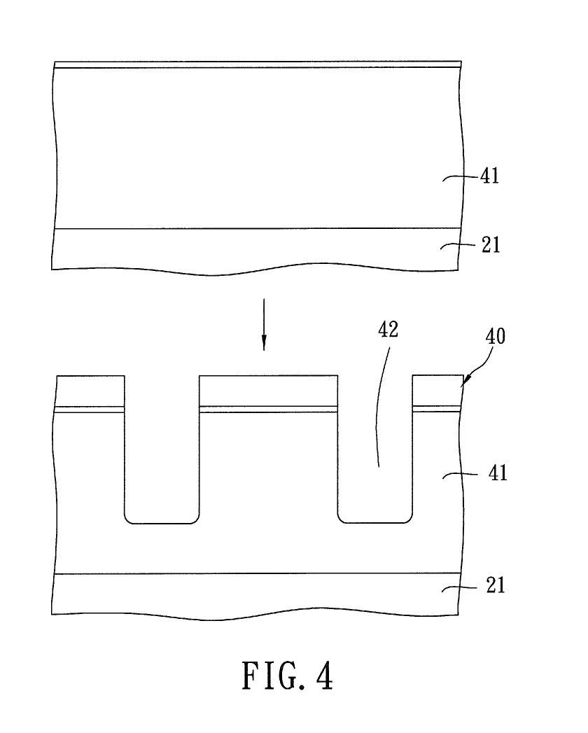

In the following, the first preferred embodiment of a method for fabricating the semiconductor device is described with reference to FIGS. 4 to 6. For clarity, the elements are described in singular form.

Referring to FIG. 4, an n-type substrate 21 is formed on a silicon wafer (not shown), and an n-type epitaxial layer 41 is grown on an upper surface of the substrate 21. Then, the epitaxial layer 41 is subjected to lithography and etching processes using a mask 40 so as to form a trench 42 that extends from a top face of the epitaxial layer 41 toward the substrate 21.

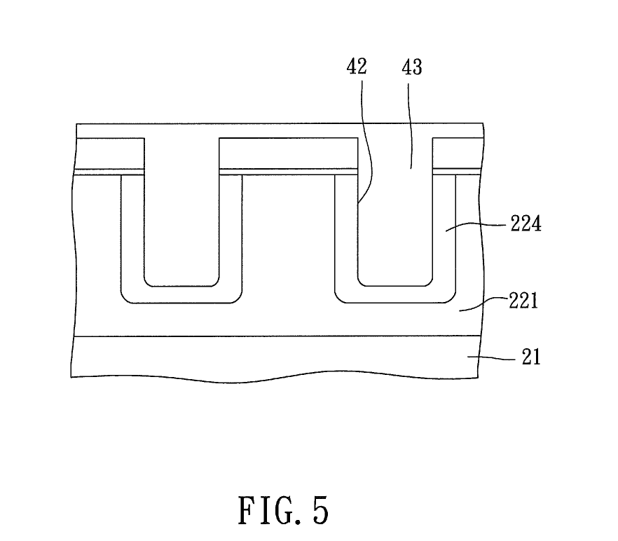

Next, as shown in FIG. 5, a p-type filling material 43 is filled in the trench 42 using an epitaxial process, and a furnace tube heating process or an instantaneous heating process is performed so that p-type carriers are diffused from the p-type filling material 43 into the epitaxial layer 41, and so that the epitaxial layer 41 is formed into a diffusion region 224 that is diffused with the p-type carriers, and a base part 221 that is not diffused with the p-type carriers and that is the n-type. An interface between the diffusion region 224 and the base part 221 is crystal lattice continuous and defines a super junction.

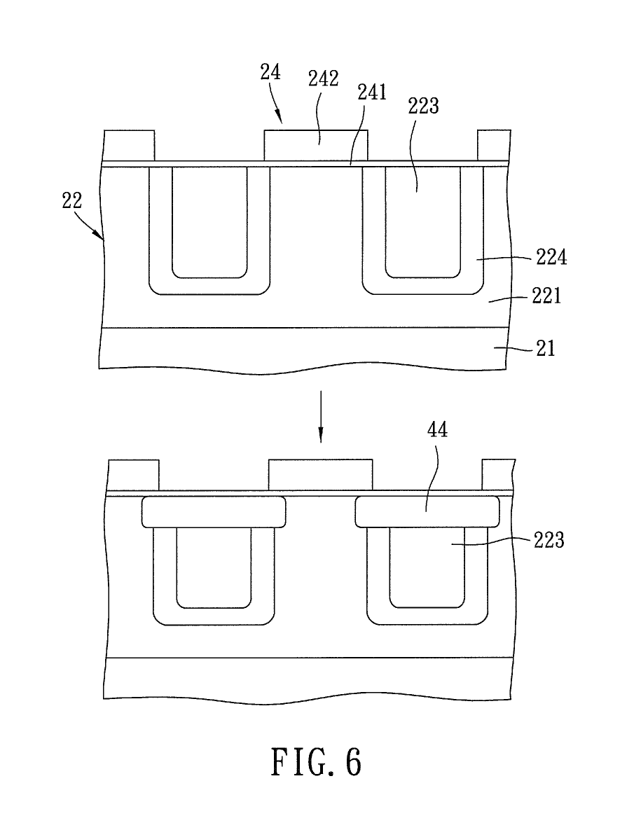

Referring to FIG. 6, the mask 40 is removed, the filling material 43 is partially removed and the remainder of the filling material 43 left in the trench 42 forms a central region 223. The central region 223 and the diffusion region 224 cooperatively define a modified part 222. A dielectric layer 241 is formed over the main body 22, and a conductive layer 242 is formed on the dielectric layer 241 to obtain a gate structure 24.

Next, the p-type carriers are implanted from a surface cooperatively defined by the diffusion region 224 and the central portion 223 and into the diffusion region 224 and the central portion 223 to form a well-forming region 44. An upper surface of the well-forming region 44 is connected to the dielectric layer 241.

Then, the n-type carriers are implanted into the well-forming region 44 so that the well-forming region 44 is formed into a source zone 23 that has the n-type, and a well region 225 that is not ion-implanted and that has the p-type. Finally, a contact 25, which is electrical conductive, is formed on a surface cooperatively defined by the source zone 23 and the well region 225. Accordingly, the semiconductor device of this invention, which includes the power transistor having a super junction, is obtained, as best shown in FIG. 2.

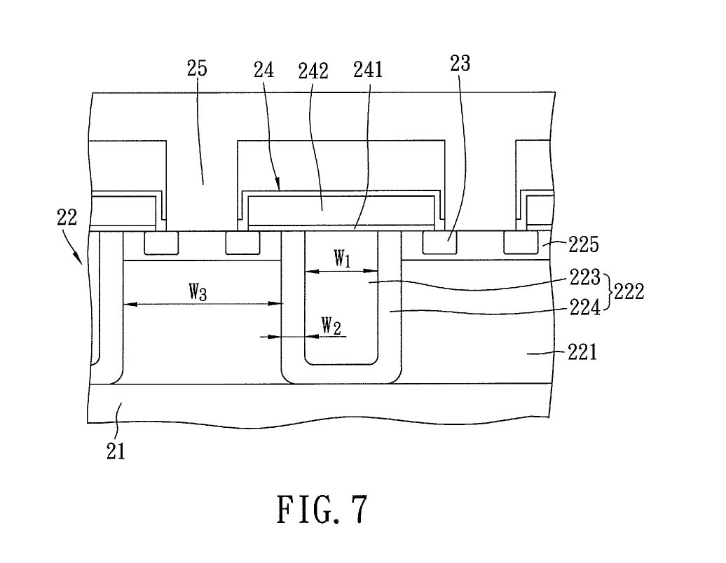

Referring to FIG. 7, the second preferred embodiment of a semiconductor device according to this invention includes a plurality of power transistors, each of which includes a substrate 21, a main body 22, a source zone 23, a gate structure 24, and a contact 25. In this embodiment, the substrate 21 is the same as that of the first preferred embodiment, and has the n-type (i.e., the first electrical type). The main body 22 includes a base part 221 and a modified part 222. The modified part 222 includes a central region 223 and a diffusion region 224. The gate structure 24 includes a dielectric layer 241 and a conductive layer 242. Like the first preferred embodiment, the first electrical type is n-type, and the second electrical type is p-type.

The second preferred embodiment differs from the first preferred embodiment in that: (1) the base part 221, and not the modified part 222, includes a well region 225 that adjoins the modified part 222, that contacts the diffusion region 224, and that surrounds and contacts the source zone 23; (2) the base part 221 has the p-type (i.e., the second electrical type), and the modified part 222 has the n-type and has a majority carrier concentration lower than that of the substrate 21; (3) the source zone 23 has the n-type and has a majority carrier concentration not lower than that of the modified part 222; and (4) the dielectric layer 241 contacts the source zone 23, the central region 223 and the diffusion region 224.

When a predetermined voltage is applied between the substrate 21 and the conductive layer 242 of the gate structure 24 that correspond to the source zone 23, the voltage on the gate structure 24 makes the well region 225 to form a channel for passage of electrical charges so that a current from the substrate 21 passes through the channel and to the source zone 23, thereby actuating the power transistor. Besides, when the predetermined voltage is maintained between the substrate 21 and the source zone 23, and when there is no voltage difference between the gate structure 24 and the source zone 33, the semiconductor device is switched off.

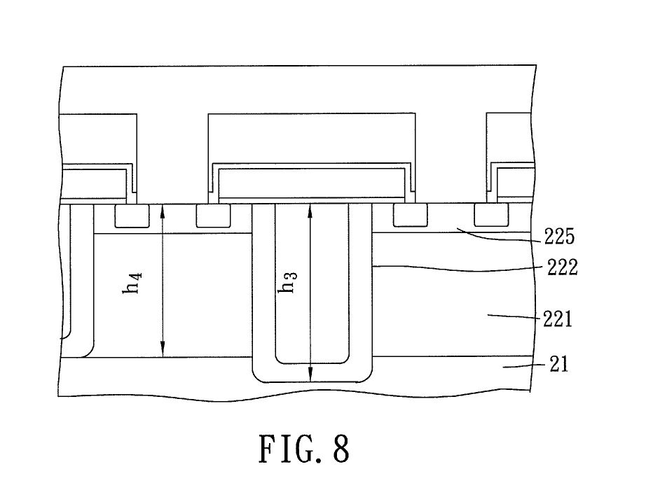

In this embodiment, the modified part 222 has a height (h3) less than a sum of a height (h4) of the base part 221 and a height of the substrate 21. In FIG. 7, a bottom end of the modified part 222 does not extend into the substrate 21. Alternatively, referring to FIG. 8 which shows a modification of the second preferred embodiment, the bottom end of the modified part 222 can extend into the substrate 21, but does not penetrate through the substrate 21, i.e., the substrate 21 should be continuous, such that the power transistors can be parallelly connected.

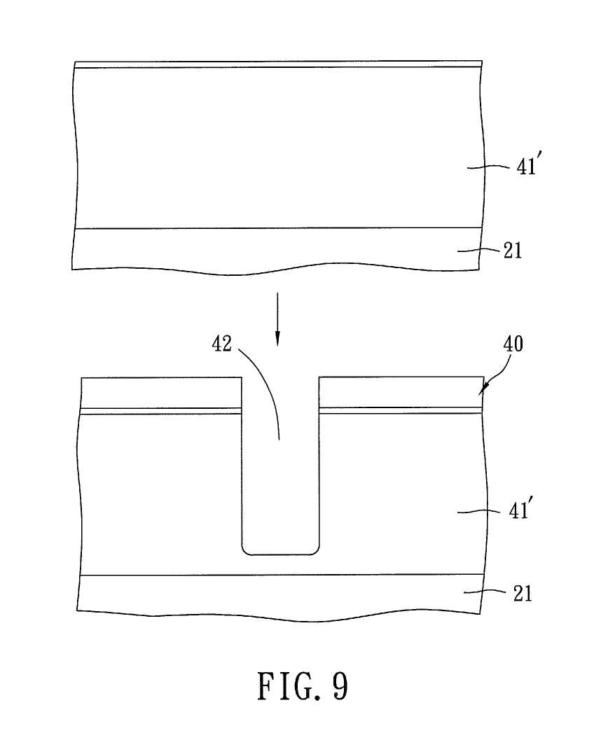

In the following, the second preferred embodiment of a method for fabricating the semiconductor device is described with reference to FIGS. 9 to 11. For clarity, the elements are described in singular form.

Referring to FIG. 9, an n-type substrate 21 is formed on a silicon wafer (not shown), and a p-type epitaxial layer 41′ is grown on an upper surface of the substrate 21. Then, the epitaxial layer 41′ is subjected to lithography and etching processes using a mask 40 so as to form a trench 42 that extends from a top face of the epitaxial layer 41′ toward the substrate 21.

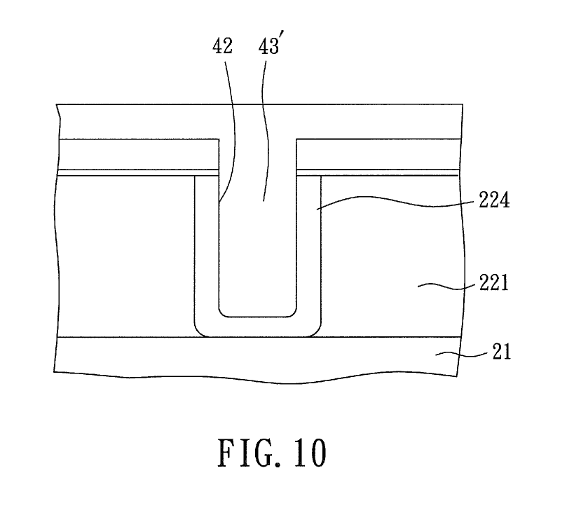

Next, as shown in FIG. 10, an n-type filling material 43′ is filled in the trench 42 using an epitaxial process, and a furnace tube heating process or an instantaneous heating process is performed so that n-type carriers are diffused from the n-type filling material 43′ into the epitaxial layer 41′, and so that the epitaxial layer 41′ is formed into a diffusion region 224 that is diffused with the n-type carriers, and a base part 221 that is not diffused with the n-type carriers and that is the p-type. An interface between the diffusion region 224 and the base part 221 is crystal lattice continuous and defines a super junction.

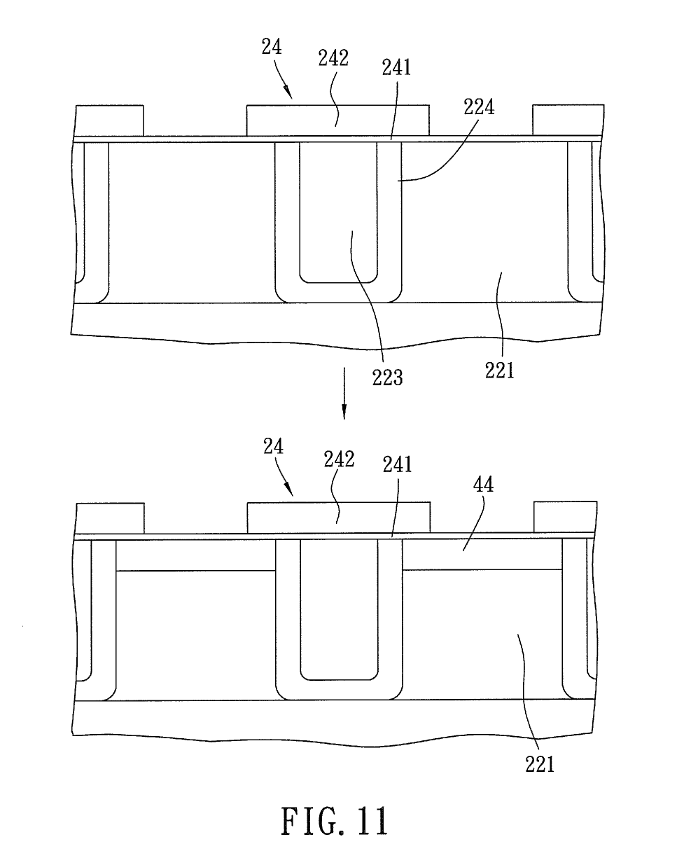

Referring to FIG. 11, the mask 40 is removed, a central region 223 is obtained by partially removing the filling material 43′, a dielectric layer 241 is formed over the modified part 222, and a conductive layer 242 is formed on the dielectric layer 241 to obtain a gate structure 24.

Next, the p-type carriers are implanted into the base part 221 to from a well-forming region 44.

Then, the n-type carriers are implanted into the well-forming region 44 so that the well-forming region 44 is formed into a source zone 23 that has the n-type, and a well region 225 that is not ion-implanted and that has the p-type (see FIG. 7). Finally, a contact 25, which is electrically conductive, is formed on a surface cooperatively defined by the source zone 23 and the well region 225. Accordingly, the semiconductor device of this invention, which includes the power transistor having a super junction, is obtained.

It should be noted that, in the previous preferred embodiments, the width of the modified part 222 is determined by the width (W2) of the diffusion region 224 which can vary by controlling the time and temperature of the diffusion step of the filling material, thereby obtaining a desired electrical property of the semiconductor device.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A semiconductor device having a super junction, comprising:
a substrate made of a semiconductor material;
a main body that is disposed on said substrate and that includes a base part and a modified part that contacts said base part and that has an electrical type opposite to that of said base part, said modified part including a central region, and a diffusion region that surrounds said central region to separate said central region from said base part, and that is crystal lattice continuous to said base part;
a gate structure having a dielectric layer formed on said main body oppositely of said substrate and a conductive layer formed on said dielectric layer oppositely of said main body; and
a source zone that is formed in said main body and that contacts said dielectric layer of said gate structure.

2. The semiconductor device of claim 1, wherein said modified region further includes a well region that is disposed on said central region and said diffusion region and that has an electrical type opposite to that of said source zone, said well region surrounding and contacting said source zone.

3. The semiconductor device of claim 2, wherein each of said substrate, said base part, and said source zone has a first electrical type, said modified part having a second electrical type opposite to the first electrical type, said base part having a carrier concentration lower than that of said substrate, said source zone having a carrier concentration not lower than that of said base part.

4. The semiconductor device of claim 1, wherein said base part further includes a well region that adjoins said modified part and contacts said diffusion part, and that has an electrical type opposite to that of said source zone, said well region surrounding and contacting said source zone.

5. The semiconductor device of claim 4, wherein each of said substrate, said modified part, and said source zone has a first electrical type, said base part having a second electrical type opposite to the first electrical type, said modified part having a carrier concentration lower than that of said substrate, said source zone having a carrier concentration not lower than that of said modified part.

6. The semiconductor device of claim 1, wherein said diffusion region has a carrier concentration gradually reduced from an outer surface of said central region to said base part.

7. The semiconductor device of claim 1, wherein said main body includes two of said modified parts, and said central region of each of said modified parts has a width not greater than a distance between said modified parts.

8. The semiconductor device of claim 7, wherein the width of said central region of each of said modified parts is not greater than five-seventh of the distance between said modified parts, and said diffusion region of each of said modified parts has a shortest width not less than one-fifth of the width of said central region of each of said modified parts.

9. The semiconductor device of claim 1, wherein said modified part has a height less than a sum of a height of said base part and a height of said substrate.
